(19) United States
(12) Patent Application Publication
(10) Pub. No.: US 2003/0172339 A1
(43) Pub. Date: Sep. 11, 2003

(54) Method for error correction decoding in a magnetoresistive solid-state storage device

(76) Inventors: James Andrew Davis, Richmond, VA (US); Jonathan Jedwab, London (GB); Gadiel Seroussi, Cupertino, CA (US); David Murray Banks, Bristol (GB); David H. McIntyre, Boise, ID (US); Stewart R. Wyatt, Boise, ID (US)

Correspondence Address: C/O LADAS & PARRY, Suite 2100, 5670 Wilshire Boulevard, Los Angeles, CA, 90036-5679, US

(21) Appl. No.: 10/093,834

(22) Filed: Mar. 8, 2002

(51) Int. Cl. G11C 29/00

(52) U.S. Cl. 714/763

(57) ABSTRACT

A magnetoresistive solid-state storage device (MRAM) employs error correction coding (ECC) to form ECC encoded stored data. A linear error correction block code such as a Reed-Solomon code forms codewords having a plurality of symbols. In almost all cases, a corrected codeword is formed by error correction decoding a read codeword in a standard first decoder arranged to reliably identify and correct up to a predetermined number of failed symbols, or else determine an unrecoverable error. Error correction decoding of the read codeword is then attempted in a stronger second decoder, ideally being a maximum likelihood decoder arranged to form one or more closest corrected codewords. Optionally, erasure information predicting failed symbols is used to enhance the error correction decoding

The present invention relates in general to a magnetoresistive solid-state storage device employing error correction coding (ECC), and in particular relates to a method for error correction decoding of ECC encoded data stored in the device.

A typical solid-state storage device comprises one or more arrays of storage cells for storing data. Existing semiconductor technologies provide volatile solid-state storage devices suitable for relatively short term storage of data, such as dynamic random access memory (DRAM), or devices for relatively longer term storage of data such as static random access memory (SRAM) or non-volatile flash and EEPROM devices. However, many other technologies are known or are being developed.

Recently, a magnetoresistive storage device has been developed as a new type of non-volatile solid-state storage device (see, for example, EP-A-0918334 Hewlett-Packard). The magnetoresistive solid-state storage device is also known as a magnetic random access memory (MRAM) device. MRAM devices have relatively low power consumption and relatively fast access times, particularly for data write operations, which renders MRAM devices ideally suitable for both short term and long term storage applications.

A problem arises in that MRAM devices are subject to physical failure, which can result in an unacceptable loss of stored data. In particular, currently available manufacturing techniques for MRAM devices are subject to limitations and as a result manufacturing yields of acceptable MRAM devices are relatively low. Although better manufacturing techniques are being developed, these tend to increase manufacturing complexity and cost. Hence, it is desired to apply lower cost manufacturing techniques whilst increasing device yield. Further, it is desired to increase cell density formed on a substrate such as silicon, but as the density increases manufacturing tolerances become increasingly difficult to control leading to higher failure rates and lower device yields.

A further problem arises in that, when error correction coding is applied to stored data, it is possible (although extremely unlikely) that part of the MRAM device is affected by so many physical failures that a standard decoding of a block of stored ECC encoded data is not possible, leading to an unrecoverable error. It is desired to identify that an unrecoverable error has occurred, and ideally it is desired to provide at least some form of recovered information from this block of ECC encoded data.

Another problem arises in that for the currently available manufacturing techniques for MRAM devices, it is desired to tolerate many physical failures. In particular, the devices are at a relatively early stage of commercial scale development. Here, it is proposed to employ a relatively heavy-duty error correction coding scheme. However, a relatively complex decoder is then required, whereas it is preferable to employ a simpler and more cost-effective decoder.

An aim of the present invention is to provide a method for error correction decoding of ECC encoded data stored in an MRAM device, wherein effectiveness of an ECC scheme is maximised, and/or where overhead associated with error correction coding can be reduced. A preferred aim is to provide such a method whereby a relatively large number of physical failures can be tolerated.

According to a first aspect of the present invention there is provided a method for error correction decoding of ECC encoded data stored in a magnetoresistive solid-state storage device having a plurality of magnetoresistive storage cells, comprising the steps of: reading a block of ECC encoded data from a set of the storage cells, the read block having been formed by an error correction block code and comprising a plurality of symbols; attempting to error correction decode the read block in a first decoder arranged to reliably identify and correct up to a predetermined threshold number of failed symbols, to form a first corrected block; determining an unrecoverable error in the first decoder, and if so error correction decoding the read block in a second decoder arranged to reliably identify and correct greater than the predetermined threshold number of failed symbols, to form one or more second corrected blocks from the read block.

In one embodiment, the predetermined threshold number of the first decoder is less than a maximum guaranteed power of the error correction block code used to form the read block, whilst the second decoder is preferably arranged to decode at least up to the maximum guaranteed power. In another embodiment, the predetermined threshold number in the first decoder is equal to the maximum guaranteed power of the error correction block code used to form the read block, and preferably the second decoder is arranged to decode beyond the maximum guaranteed power (i.e. minimum distance) of the error correction block code used to form the read block.

Preferably, the read block comprises a codeword of ECC encoded data.

The second decoder is preferably a maximum likelihood decoder arranged to output a closest valid codeword or set of closest valid codewords, from the read codeword.

Preferably, the error correction code is a linear error correction code and ideally is a Reed-Solomon code.

The method preferably comprises generating erasure information for the read codeword identifying zero or more symbols predicted to be failed symbols, and error correction decoding the read codeword with reference to the erasure information.

The method may further comprise the steps of: encoding a logical unit of original information to form at least codeword of ECC encoded data; and storing the at least one codeword of ECC encoded data in the array of storage cells; wherein the decoding step attempts to recover the logical unit of original information from the stored at least one codeword of ECC encoded data.

According to a second aspect of the present invention there is provided a method for error correction decoding of ECC encoded data stored in a magnetoresistive solid-state storage device having a plurality of magnetoresistive storage cells, comprising the steps of: reading a codeword of ECC encoded data from a set of the storage cells, the read codeword having been formed by an error correction block code and comprising a plurality of symbols; error correction decoding the read codeword in a first decoder arranged to reliably identify and correct up to a predetermined threshold number of failed symbols in the read codeword, to provide a corrected codeword or else determining an unrecoverable error; and in response to the unrecoverable error, error correction decoding the read codeword in a second decoder arranged to reliably correct greater than the predetermined threshold number of failed symbols in the codeword.

According to another aspect of the present invention there is provided a magnetoresistive solid-state storage device, comprising: a plurality of magnetoresistive storage cells arranged in at least one array; a controller arranged to read a codeword of ECC encoded data from a set of the storage cells, the read codeword having been formed by an error correction block code and comprising a plurality of symbols; a first decoder arranged to error correction decode the read codeword by reliably identifying and correcting up to a predetermined threshold number of failed symbols in the read codeword, to provide a corrected codeword or else to determine an unrecoverable error; and a second decoder arranged to error correction decode the read codeword by reliably correcting greater than the predetermined threshold number of failed symbols in the codeword.

The invention also extends to apparatus incorporating a magnetoresistive storage device as defined herein.

For a better understanding of the invention, and to show how embodiments of the same may be carried into effect, reference will now be made, by way of example, to the accompanying diagrammatic drawings in which:

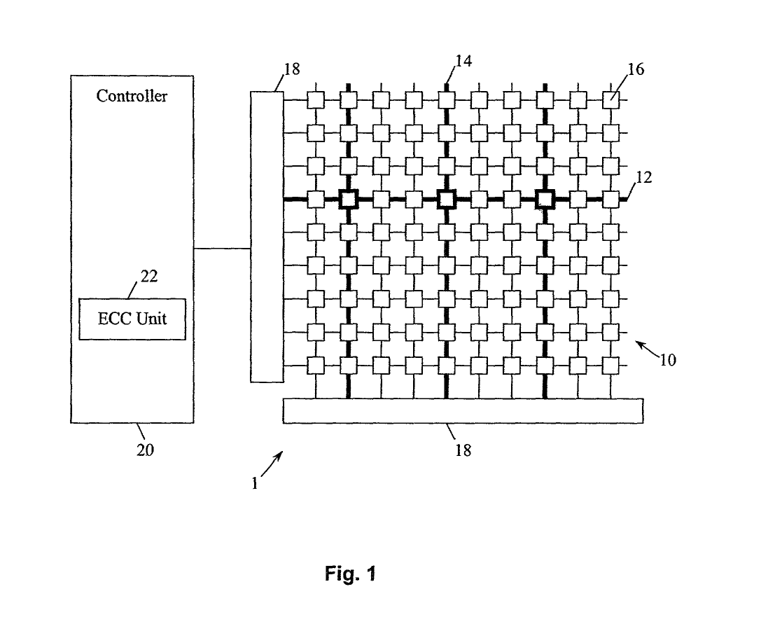

FIG. 1 is a schematic diagram showing a preferred MRAM device including an array of storage cells;

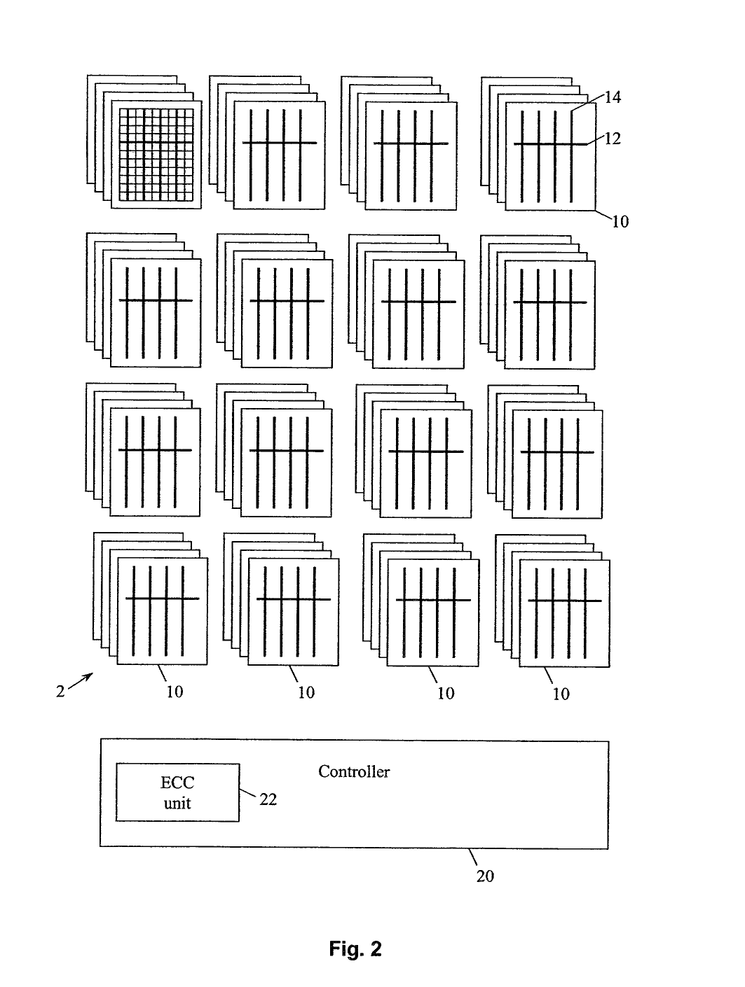

FIG. 2 shows a preferred MRAM device in more detail;

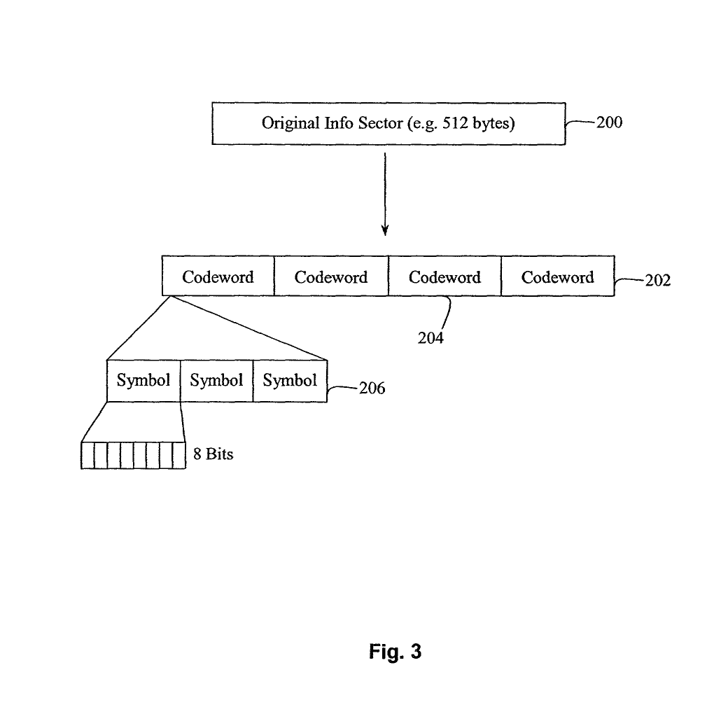

FIG. 3 shows a preferred logical data structure;

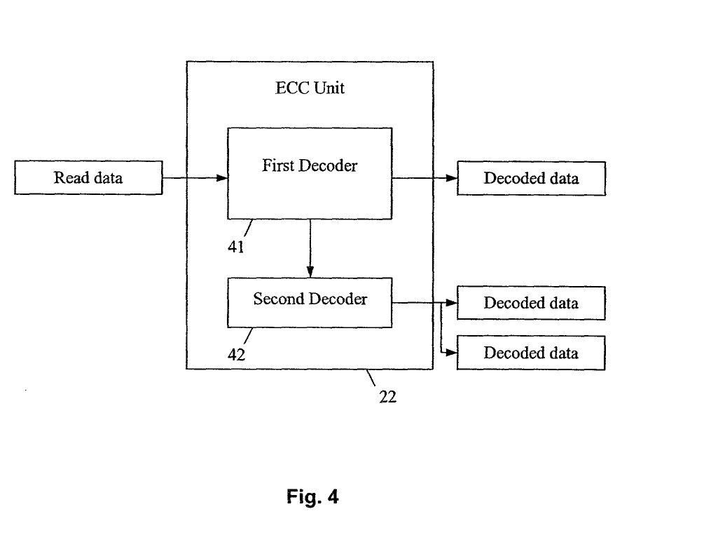

FIG. 4 is a schematic diagram showing a controller of the preferred MRAM device in more detail;

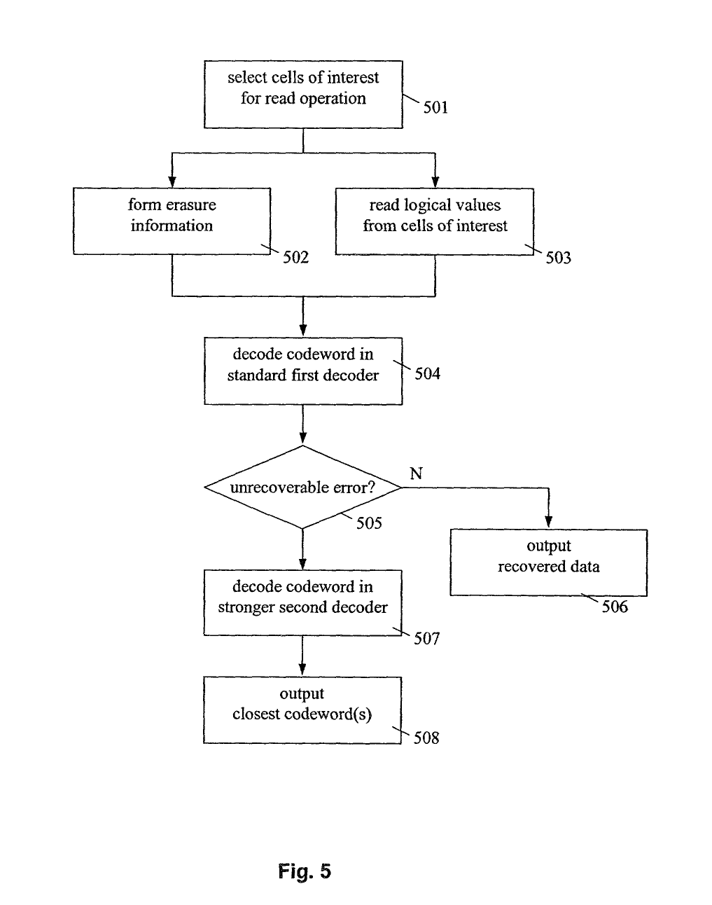

FIG. 5 shows a preferred method for decoding ECC encoded data stored in the device.

To assist a complete understanding of the present invention, an example MRAM device will first be described with reference to FIGS. 1 and 2, including a description of the failure mechanisms found in MRAM devices. The error correction decoding arrangements adopted in the preferred embodiments of the present invention aim to minimise the adverse effects of such physical failures and are described with reference to FIGS. 3, 4 and 5.

FIG. 1 shows a simplified magnetoresistive solid-state storage device 1 comprising an array 10 of storage cells 16. The array 10 is coupled to a controller 20 which, amongst other control elements, includes an ECC coding and decoding unit 22. The controller 20 and the array 10 can be formed on a single substrate, or can be arranged separately. EP-A-0 918 334 (Hewlett-Packard) discloses one example of a magnetoresistive solid-state storage device which is suitable for use in preferred embodiments of the present invention.

In the preferred embodiment, the array 10 comprises of the order of 1024 by 1024 storage cells, just a few of which are illustrated. The storage cells 16 are each formed at an intersection between control lines 12 and 14. In this example control lines 12 are arranged in rows, and control lines 14 are arranged in columns. The control lines 12 and 14 are generally orthogonal, but other more complicated lattice structures are also possible. Suitably, the row and column lines 12,14 are coupled to control circuits 18, which include a plurality of read/write control circuits. Depending upon the implementation, one read/write control circuit is provided per column, or read/write control circuits are multiplexed or shared between columns.

In a device access such as a write operation or a read operation, one row 12 and one or more columns 14 are selected by the control circuits 18 to access the required storage cell or cells 16 (or conversely one column and several rows, depending upon the orientation of the array). The selected cells 16, the selected row line 12, and the selected column lines 14, are each represented by bold lines in FIG. 1. The preferred MRAM device requires a minimum distance m, such as sixty-four cells, between the selected column lines 14 to minimise cross-cell interference. Given that each array 10 has rows of length l, such as 1024 storage cells, it is possible to access substantially simultaneously up to l/m=1024/64=16 cells from the array 10.

Each storage cell 16 stores one bit of data suitably representing a numerical value and preferably a binary value, i.e. one or zero. Suitably, each storage cell includes two films which assume one of two stable magnetisation orientations, known as parallel and anti-parallel. The magnetisation orientation affects the resistance of the storage cell. When the storage cell 16 is in the anti-parallel state, the resistance is at its highest, and when the magnetic storage cell is in the parallel state, the resistance is at its lowest. Suitably, the high resistance anti-parallel state defines a “0” logic state, and the low resistance parallel state defines a “1” logic state, or vice versa. In the preferred device, the resistance of each storage cell 16 is determined according to a phenomenon known as spin tunnelling and the cells are referred to as magnetic tunnel junction storage cells. The condition of the storage cell is determined by measuring the sense current (proportional to resistance) or a related parameter such as response time to discharge a known capacitance, which gives one or more parametric values for each storage cell. A logical value can then be derived from the obtained parametric value or values. Depending upon the nature and construction of the MRAM device, the read operation may comprise multiple steps or require combined read and rewrite actions.

FIG. 2 shows the preferred MRAM device in more detail. A macro-array 2 is formed comprising a large plurality of individual arrays 10, each of which is formed as discussed above for FIG. 1. The use of plural arrays advantageously allows an MRAM device to be obtained of a desired overall data storage capacity, without the individual arrays 10 in themselves becoming so large that they are difficult to manufacture or control. For simplicity, FIG. 2 shows only a portion of the macro-array.

Many design choices are available to the skilled person when laying out the arrays 10 on a suitable substrate during manufacture of the device, but, amongst other concerns, it is commonly desired to reduce substrate area for each device. Conveniently, it has been found that the arrays 10 can be manufactured in layers. In the example of FIG. 2, four arrays 10 are layered to form a stack. In an example practical device having a storage capacity of the order of 128 Mbytes, 1024 arrays are arranged in a macro-array of 16 arrays wide, by 16 arrays high, with four stack layers. In other preferred devices, ECC encoded data is stored in 1152 arrays arranged 16 wide by 18 high with 4 stack layers, giving a total capacity of 144 Mbytes, or 1280 arrays arranged 16 wide by 20 high by 4 stack layers giving 160 Mbytes. Optionally, the MRAM device comprises more than one such macro-array.

As illustrated in FIG. 2, the preferred method for accessing the MRAM device 1 comprises selecting one row 12 in each of a plurality of arrays 10, and selecting plural columns 14 from each of the plurality of arrays to thereby select a plurality of storage cells 16. The accessed cells within each of the plurality of arrays correspond to a small portion of a unit of data. Together, the accessed cells provide a whole unit of data, such as a whole sector unit, or at least a substantial portion of the unit. Advantageously, each of the plurality of arrays are accessible substantially simultaneously. Therefore, device access speed for a read operation or a write operation is increased. This device access is conveniently termed a slice through the macro-array.

As shown in FIG. 2, it is convenient for the same row address and the same column addresses to be selected in each of the plurality of arrays. That is, a unit of data is stored across a plurality of arrays, using the same row and column addresses within each of the plurality of arrays.

As also shown in FIG. 2, in the preferred construction the arrays 10 are layered to form stacks. Only one array within each stack can be accessed at any one time. Therefore, it is convenient that the plurality of arrays used to store a sector unit of data are each in different stacks (i.e. none of the selected plurality of arrays are in the same stack). Also, it is convenient to select arrays which are all in the same layer. Ideally, one array is selected from each stack, the arrays each being in the same layer within each stack. In the example of FIG. 2, the topmost array within each stack has been selected.

Most conveniently, the number of arrays available in the macro-array 2 is matched to the size of a sector unit of data to be stored in the device. Here, it is convenient to provide the total number of arrays such that, given the number of cells which can be substantially simultaneously accessed in an array, a sector unit is stored using cells within all of the arrays of a single layer of the device, to store a whole sector unit of data. In other preferred embodiments, it is convenient for a reciprocal integer fraction of a sector unit of data (e.g. one half or one third or one quarter of a sector unit) to be accessible substantially simultaneously.

Although generally reliable, it has been found that failures can occur which affect the ability of the device to store data reliably in the storage cells 16. Physical failures within a MRAM device can result from many causes including manufacturing imperfections, internal effects such as noise in a read process, environmental effects such as temperature and surrounding electromagnetic noise, or ageing of the device in use. In general, failures can be classified as either systematic failures or random failures. Systematic failures consistently affect a particular storage cell or a particular group of storage cells. Random failures occur transiently and are not consistently repeatable. Typically, systematic failures arise as a result of manufacturing imperfections and ageing, whilst random failures occur in response to internal effects and to external environmental effects.

Failures are highly undesirable and mean that at least some storage cells in the device cannot be written to or read from reliably. A cell affected by a failure can become unreadable, in which case no logical value can be read from the cell, or can become unreliable, in which case the logical value read from the cell is not necessarily the same as the value written to the cell (e.g. a “1” is written but a “0” is read). The storage capacity and reliability of the device can be severely affected and in the worst case the entire device becomes unusable.

Failure mechanisms take many forms, and the following examples are amongst those identified:

1. Shorted bits—where the resistance of the storage cell is much lower than expected. Shorted bits tend to affect all storage cells lying in the same row and the same column.

2. Open bits—where the resistance of the storage cell is much higher than expected. Open bit failures can, but do not always, affect all storage cells lying in the same row or column, or both.

3. Half-select bits—where writing to a storage cell in a particular row or column causes another storage cell in the same row or column to change state. A cell which is vulnerable to half select will therefore possibly change state in response to a write access to any storage cell in the same row or column, resulting in unreliable stored data.

4. Single failed bits—where a particular storage cell fails (e.g. is stuck always as a “0”), but does not affect other storage cells and is not affected by activity in other storage cells.

These four example failure mechanisms are each systematic, in that the same storage cell or cells are consistently affected. Where the failure mechanism affects only one cell, this can be termed an isolated failure. Where the failure mechanism affects a group of cells, this can be termed a grouped failure.

Whilst the storage cells of the MRAM device can be used to store data according to any suitable logical layout, data is preferably organised into basic sub-units (e.g. bytes) which in turn are grouped into larger logical data units (e.g. sectors). A physical failure, and in particular a grouped failure affecting many cells, can affect many bytes and possibly many sectors. It has been found that keeping information about each small logical sub-unit (e.g. bytes) affected by physical failures is not efficient, due to the quantity of data involved. That is, attempts to produce a list of all such logical units rendered unusable due to at least one physical failure, tend to generate a quantity of management data which is too large to handle efficiently. Further, depending on how the data is organised on the device, a single physical failure can potentially affect a large number of logical data units, such that avoiding use of all bytes, sectors or other units affected by a failure substantially reduces the storage capacity of the device. For example, a grouped failure such as a shorted bit failure in just one storage cell affects many other storage cells, which lie in the same row or the same column. Thus, a single shorted bit failure can affect 1023 other cells lying in the same row, and 1023 cells lying in the same column—a total of 2027 affected cells. These 2027 affected cells may form part of many bytes, and many sectors, each of which would be rendered unusable by the single grouped failure.

Some improvements have been made in manufacturing processes and device construction to reduce the number of manufacturing failures and improve device longevity, but this usually involves increased manufacturing costs and complexity, and reduced device yields.

The preferred embodiments of the present invention employ error correction coding to provide a magnetoresistive solid-state storage device which is error tolerant, preferably to tolerate and recover from both random failures and systematic failures. Typically, error correction coding involves receiving original information which it is desired to store and forming encoded data which allows errors to be identified and ideally corrected. The encoded data is stored in the solid-state storage device. At read time, the original information is recovered by error correction decoding the encoded stored data. A wide range of error correction coding (ECC) schemes are available and can be employed alone or in combination.

As general background information concerning error correction coding, reference is made to the following publication: W.W. Peterson and E. J. Weldon, Jr., “Error-Correcting Codes”, 2^{nd} edition, 12^{th} printing, 1994, MIT Press, Cambridge Mass.

A more specific reference concerning Reed-Solomon codes used in the preferred embodiments of the present invention is: “Reed-Solomon Codes and their Applications”, ED. S. B. Wicker and V. K. Bhargava, IEEE Press, New York, 1994.

FIG. 3 shows an example logical data structure used when storing data in the MRAM device 10. Original information 200 is received in predetermined units such as a sector comprising 512 bytes. Error correction coding is performed to produce ECC encoded data, in this case an encoded sector 202. The encoded sector 202 comprises a plurality of symbols 206 which can be a single bit (e.g. a BCH code with single-bit symbols) or can comprise multiple bits (e.g. a Reed-Solomon code using multi-bit symbols). In the preferred Reed-Solomon encoding scheme, each symbol 206 conveniently comprises eight bits and, as shown in FIG. 3, each encoded sector 202 comprises four codewords 204, each comprising of the order of 144 to 160 symbols. The eight bits corresponding to each symbol are conveniently stored in eight storage cells 16, which can be termed a symbol group. A physical failure which directly or indirectly affects any of these eight storage cells in a symbol group can result in one or more of the bits being unreliable (i.e. the wrong value is read) or unreadable (i.e. no value can be obtained), giving a failed symbol.

In the current MRAM devices, grouped failures tend to affect a large group of storage cells, sharing the same row or column. This provides an environment which is unlike prior storage devices. The preferred embodiments of the present invention employ an ECC scheme with multi-bit symbols. Where manufacturing processes and device design change over time, it may become more appropriate to organise storage locations expecting bit-based errors and then apply an ECC scheme using single-bit symbols, and at least some of the following embodiments can be applied to single-bit symbols.

Error correction decoding each block of stored ECC encoded data allows failed symbols 206 to be identified and corrected. Conveniently, decoding is performed independently for each block of ECC encoded data, such as an ECC encoded sector 202 or, in the preferred embodiment, for each codeword 204. Hence, the encoded sector 202, or preferably each ECC codeword 204, forms the unit of data to be stored in the device.

The preferred Reed-Solomon scheme is an example of an error correction block code, and conveniently a linear error correcting code, which mathematically identifies and corrects completely up to a predetermined maximum number of failed symbols 206 within each independently decodeable block of ECC encoded data, depending upon the power of the code. For example, a [160,128,33] Reed-Solomon code producing codewords having one hundred and sixty 8-bit symbols corresponding to one hundred and twenty-eight original information bytes and a minimum distance of thirty-three symbols can locate and correct any pattern of up to sixteen symbol errors.

Suitably, the ECC scheme employed is selected with a power sufficient to recover original information 200 from the encoded data in substantially all cases. Pictorially, each perfect block of ECC encoded data represents a point in space, and a reliably correctable form of that block of ECC encoded data lies within a “ball” having a radius corresponding to the maximum guaranteed power of the ECC encoding scheme. Very rarely, a block of encoded data is encountered which is affected by so many failures that the original information 200 is unrecoverable. Here, the ECC decoding unit 22 is presented with a block of ECC encoded data which is so severely affected by physical failures that it lies outside the ball of all reliably correctable blocks of ECC encoded data. Also, even more rarely, the failures result in a mis-correct, where information recovered from the encoded data 202 is not equivalent to the original information 200. Even though the recovered information does not correspond to the original information, a mis-correct is not readily determined. Pictorially, the ECC decoding unit 22 is presented with a block of ECC encoded data which is so severely affected by physical failures that it lies inside an incorrect ball, i.e. not the ball corresponding to the perfect form of that block of ECC encoded data. Ideally, the ECC scheme is selected such that the probability of encountering an unrecoverable or mis-corrected block of ECC encoded data is extremely small, suitably of the order of 10⁻¹⁵ to 10⁻²⁰.

It is desired to minimise the probability that original information is unrecoverable from a block of stored encoded data or that a mis-correct occurs. Therefore, the preferred embodiments of the invention aim to improve effective use of an error correction coding scheme, as will be described below. Also, it is desired to tolerate a relatively large number of failed symbols within a block of ECC encoded data, whilst employing a simple and low-cost decoder.

Advantageously, in the preferred embodiments of the invention, failed cells amongst a set of cells of interest in a read operation are predicted, which allows error correction decoding of ECC encoded data stored in the MRAM device to be significantly enhanced. The predicted failures allow erasure information to be formed for a block of ECC encoded data read from the MRAM device 1. The failures can be predicted by any suitable mechanism. As illustrative examples, failed cells can be identified by a parametric test of each cell at read time, or by examining a related set of test cells, or by maintaining a history of parts of the device affected by failures (e.g. identifying rows and/or columns of cells affected by grouped-type failures).

FIG. 4 is a schematic diagram showing the controller 20 of the preferred MRAM device in more detail. A first decoder 41 and a second decoder 42 are provided. At least the first decoder 41 is provided integral with the ECC coding and decoding unit 22 of the controller 20. The second decoder 41 is provided either as part of the ECC coding and decoding unit 22, or may be provided as a stand-alone unit. Here, the second decoder 42 is preferably coupled to the MRAM device only when required.

The first decoder 41 is arranged to reliably identify and correct up to a predetermined threshold number of failed symbols in the read codeword, and thereby to output a corrected codeword. The threshold number is suitably equal to or less than the maximum guaranteed power of the ECC encoding scheme. The first decoder 41 is arranged to determine an unrecoverable error. Very rarely, when an unrecoverable error is identified, the second decoding unit 42 is employed to perform a stronger form of error correction decoding on the read codeword.

Advantageously, the first decoder 41 can be simplified and implemented at relatively low cost, because the first decoder 41 is designed to implement only up to the desired threshold number.

In a first embodiment, the threshold is set to provide the first decoder 41 with a limited capacity, less than the maximum guaranteed power of the ECC scheme, but which is relatively fast to operate. For example, in the preferred Reed-Solomon [160,128,33] scheme having a minimum distance of t=33 symbols, the maximum guaranteed power is (t−1)/2=16 full errors, but the threshold is set to be of the order of 8, 10 or 12 full errors. The second decoder then implements the maximum guaranteed power of the decoding scheme, to be available in those rarer cases when a stronger decoder is required.

In another embodiment, the first decoder 41 implements the maximum guaranteed power of the decoding scheme (e.g. 16 full errors), whilst the stronger second decoder 42 is arranged to decode beyond the designed distance of the ECC scheme (e.g. 17, 18 or more full errors). Here, the first decoder takes advantage of the maximum standard power of the ECC scheme, and the second decoder allows recovered information to be produced in those rare cases where a block of data is affected beyond the that maximum guaranteed power.

The second decoder is ideally a maximum likelihood decoder, also termed a coset leader decoder, or a complete decoder. Suitably, the stronger second decoder 42 is arranged to form one or more closest corrected codewords.

An example Reed-Solomon decoder suitable for use as the second decoder is discussed in more detail in: “Improving decoding of Reed-Solomon and algebraic-geometry code”, V. Guruswami and M. Sudan, IEEE Transactions on Information Theory, Vol 45, issue 6, September 1999, pp 1755-1764.

Another suitable decoder is discussed in “Efficient decoding of Reed-Solomon codes beyond half the minimum distance”, R. Roth and G. Ruckenstein, IEEE Transactions on Information Theory, Vol 46, issue 1, January 2000, pp 246-257.

A practical limitation of these example stronger decoders is that as the number of permitted failed symbols is increased, the complexity of the decoder increases very rapidly. Hence, it is desired to use the standard first decoder for almost all decoding work, and to employ the stronger second decoder only relatively infrequently. Also, in the nature of MRAM devices, it is most likely that an unrecoverable error will occur with only one greater failed symbol than the maximum number allowed in the first decoder, with a still smaller probability for two extra failed symbols and reducing successively for each extra failed symbol. Hence, it has been found that these example decoders are well suited to the environment of MRAM devices.

FIG. 5 shows a preferred method for decoding of ECC encoded data stored in a MRAM device. Preferably, the MRAM device 1 is configured as discussed above in FIGS. 1, 2 and 4, and the stored data is error correction encoded into a format as shown in FIG. 3.

Step 501 comprises selecting a set of storage cells 16 of interest in a read operation. Conveniently, the selected set of storage cells correspond to at least one block of ECC encoded data, such as a codeword 204 or a complete encoded sector 202.

Step 502 comprises optionally forming erasure information by predicting failures amongst the cells of interest.

Step 503 comprises reading logical values from the set of storage cells 16 of interest in the read operation. Optionally, this read process is repeated, in the hope of avoiding a transient or random error. However, particularly with currently available MRAM devices, a small number of systematic failures are to be expected when accessing any significant number of storage cells, such as the set of storage cells corresponding to an ECC codeword 204 or an encoded sector 202.

The logical values and erasure information are obtained and presented in any suitable form. In one example, the logical bit values are determined with hard decisions as to the value of each bit, or else the bit is determined as a failure and erasure information is generated accordingly. In a second example, soft decisions are made as to the relative certainty with which erasure information is generated. For example, the cells are ranked in order of quality, and only the n most severely affected cells amongst the cells of interest lead to erasures. Ideally, the logical symbol values and the erasure information are arranged to form an input (or inputs) to the first decoder 41.

It is convenient to prepare the erasure information in parallel with generating the logical bit values. In the currently preferred embodiments, each storage cell 16 stores a single logical bit value representing a binary 1 or 0, and multiple bits are gathered together to form a symbol 206. Preferably, the erasure information is prepared on the basis that a symbol 206 is declared as an erasure where any one or more of the cells in a symbol group storing that symbol are predicted to be a failed storage cell 163.

Step 504 comprises error correction decoding the block of stored ECC encoded data, using the symbol logical values and optionally taking account of the erasure information. This step is performed in the first decoder 41. In the preferred ECC coding scheme, each codeword 204 is decoded in isolation, and the results from ECC decoding plural codewords (in this case four codewords) provides ECC decoded data corresponding to the original information sector 200. As will be familiar to those skilled in the field of ECC, available error correction codes allow a predetermined number of full errors to be corrected (i.e. where the location of a symbol error is unknown and the symbol value is unknown), and twice that predetermined number of erasures (i.e. where the location of a symbol error is known and just the symbol value remains unknown) or a combination of the two. For example, the preferred [160,128,33] Reed-Solomon code is mathematically able to correct up to sixteen full errors or up to thirty-two erasures (or a combination, such as twenty erasures and six full errors). Advantageously, the error correction decoding is able to correct a greater number of errors using the generated erasure information, compared with a situation where this erasure information is not available.

In step 505, it is determined whether an unrecoverable error has occurred. Such determination may take any suitable form, depending upon the upon the exact nature of the first decoder 41. In some embodiments, an unrecoverable error is detected by the existence of an expected mathematical condition. In a typical decoder, the decoding step simply fails to produce a corrected codeword, and instead indicates an unrecoverable error. Preferably, the first decoder 41 monitors the number of changed symbols, and will only attempt to output a corrected codeword if this number is below the predetermined threshold number. The threshold number suitably represents a number less than or equal to the maximum guaranteed power of the decoder. In other, less preferred, embodiments, an invalid corrected codeword is produced which can be identified because the corrected codeword contains greater than a permitted number of changed (corrected) symbols. Where an unrecoverable error is detected, the method moves to step 507. Otherwise, the method proceeds to step 506.

Optionally, remedial action is taken in respect of the set of cells of interest, when an unrecoverable error has been identified in the step 505. For example, the set of cells are made redundant and are not used again for storing data. Suitably, the data stored in those cells is moved to a less-affected part of the device.

Step 506 comprises providing an output from the decoding step, as recovered information. In the preferred embodiment, the power of the error correction coding scheme is chosen to balance an overhead of the ECC scheme against the probability of encountering failed symbols. In substantially all practical cases the number of failures is within the power of the decoder to correct, and the original information 200 is recovered and output. The loss of original information due to an unrecoverable or mis-corrected block of stored encoded data is very rare.

In step 507, a stronger error correction decoding is applied. It is desired to find the codeword or set of codewords that are closest to the read codeword, namely, the valid codeword or codewords that are most likely to have produced the read codeword. This is suitably determined by calculating the codewords having the least number of changed symbols from the read codeword. Here, the second decoder 42 is employed. The second decoder is optionally provided off-line, separate from a stream of decoding actions in the first decoder. The second decoder ideally is allowed more time to complete the longer and more complex calculations, and the results are then fed back into a decoded data stream.

The corrected codeword from the second decoder 42 is output in step 508. If the second decoding step produces a set of closest codewords, then ideally a further selection or grading is made to identify a preferred one corrected codeword amongst this set. For example, a context of the codeword is used to select a most appropriate closest codeword. Where the data stored by the codeword is text or music, then this data context may assist the selection.

The MRAM device described herein is ideally suited for use in place of any prior solid-state storage device. In particular, the MRAM device is ideally suited both for use as a short-term storage device (e.g. cache memory) or a longer-term storage device (e.g. a solid-state hard disk). An MRAM device can be employed for both short term storage and longer term storage within a single apparatus, such as a computing platform.

A magnetoresistive solid-state storage device and methods for decoding ECC encoded data stored in such a device have been described. Advantageously, the storage device is able to tolerate a relatively large number of errors, including both systematic failures and transient failures, whilst successfully remaining in operation with no loss of original data, through the use of error correction coding. A first simple standard decoder is used and succeeds in correcting the read encoded data in almost all cases. However, when part of the MRAM device is affected by so many physical failures that a standard decoding is not possible, an unrecoverable error is identified and a stronger decoder employed. A most likely correction or set of corrections is then presented. As a result, simpler and lower cost manufacturing techniques are employed and/or device yield and device density are increased. Error correction coding and decoding allows blocks of data, e.g. sectors or codewords, to remain in use, where otherwise the whole block must be discarded if only one failure occurs. Advantageously, generating erasure information allows significantly improved error correction decoding. Error correction overhead in the stored encoded data can be reduced and/or more powerful error correction can be obtained for the same overhead.

1. A method for error correction decoding of ECC encoded data stored in a magnetoresistive solid-state storage device having a plurality of magnetoresistive storage cells, comprising the steps of:
reading a block of ECC encoded data from a set of the storage cells, the read block having been formed by an error correction block code and comprising a plurality of symbols;
attempting to error correction decode the read block in a first decoder arranged to reliably identify and correct up to a predetermined threshold number of failed symbols, to form a first corrected block; and
determining an unrecoverable error in the first decoder, and if so error correction decoding the read block in a second decoder arranged to reliably identify and correct greater than the predetermined threshold number of failed symbols, to form one or more second corrected blocks from the read block.

2. The method of claim 1, wherein the predetermined threshold number is less than a maximum guaranteed power of the error correction block code used to form the read block.

3. The method of claim 1, wherein the predetermined threshold number represents a maximum guaranteed power of the error correction block code used to form the read block.

4. The method of claim 1, wherein the second decoder is arranged to decode beyond a maximum guaranteed power of the error correction block code used to form the read block.

5. The method of claim 1, wherein the second decoder is a maximum likelihood decoder arranged to output a closest valid block or set of closest valid blocks, from the read block.

6. The method of claim 1, wherein the error correction code is a linear error correction code.

7. The method of claim 1, wherein the error correction code is a Reed-Solomon code.

8. The method of claim 1, comprising generating erasure information for the read block identifying zero or more symbols predicted to be failed symbols, and error correction decoding the read block with reference to the erasure information.

9. The method of claim 1, further comprising the steps of:
encoding a logical unit of original information to form at least block of ECC encoded data; and
storing the at least one block of ECC encoded data in the array of storage cells;
wherein the decoding step attempts to recover the logical unit of original information from the stored at least one block of ECC encoded data.

10. The method of claim 1, wherein the read block comprises a codeword of ECC encoded data.

11. A method for error correction decoding of ECC encoded data stored in a magnetoresistive solid-state storage device having a plurality of magnetoresistive storage cells, comprising the steps of:
reading a codeword of ECC encoded data from a set of the storage cells, the read codeword having been formed by an error correction block code and comprising a plurality of symbols;
error correction decoding the read codeword in a first decoder arranged to reliably identify and correct up to a predetermined threshold number of failed symbols in the read codeword, to provide a corrected codeword or else determining an unrecoverable error; and
in response to the unrecoverable error, error correction decoding the read codeword in a second decoder arranged to reliably correct greater than the predetermined threshold number of failed symbols in the codeword.

12. The method of claim 11, wherein the predetermined threshold number is less than a maximum guaranteed power of the error correction block code used to form the read codeword.

13. The method of claim 11, wherein the predetermined threshold number is equal to a maximum guaranteed power of the error correction block code used to form the read codeword.

14. The method of claim 11, wherein the second decoder is arranged to decode beyond a maximum guaranteed power of the error correction block code used to form the read codeword.

15. The method of claim 11, wherein the second decoder is a maximum likelihood decoder arranged to output a closest valid codeword or set of closest valid codewords, from the read codeword.

16. The method of claim 11, wherein the error correction code is a linear error correction code.

17. The method of claim 11, wherein the error correction code is a Reed-Solomon code.

18. The method of claim 11, comprising generating erasure information for the read codeword identifying zero or more symbols predicted to be failed symbols, and error correction decoding the read codeword with reference to the erasure information.

19. The method of claim 11, further comprising the steps of:
encoding a logical unit of original information to form at least one codeword of ECC encoded data; and
storing the at least one codeword of ECC encoded data in the array of storage cells;
wherein the decoding step attempts to recover the logical unit of original information from the stored at least one codeword of ECC encoded data.

20. A magnetoresistive solid-state storage device, comprising:
a plurality of magnetoresistive storage cells arranged in at least one array;
a controller arranged to read a codeword of ECC encoded data from a set of the storage cells, the read codeword having been formed by an error correction block code and comprising a plurality of symbols;
a first decoder arranged to error correction decode the read codeword by reliably identifying and correcting up to a predetermined threshold number of failed symbols in the read codeword, to provide a corrected codeword or else to determine an unrecoverable error; and
a second decoder arranged to error correction decode the read codeword by reliably correcting greater than the predetermined threshold number of failed symbols in the codeword.

21. The method of claim 20, wherein the predetermined threshold number is less than a maximum guaranteed power of the error correction block code used to form the read codeword.

22. The method of claim 20, wherein the predetermined threshold number is equal to a maximum guaranteed power of the error correction block code used to form the read codeword.

23. The method of claim 20, wherein the second decoder is arranged to decode beyond a maximum guaranteed power of the error correction block code used to form the read codeword.

24. The device of claim 20, wherein the second decoder is a maximum likelihood decoder arranged to output a closest valid codeword or set of closest valid codewords, from the read codeword.
